(19) United States
(12) Patent Application Publication
(10) Pub. No.: US 2015/0180482 A1
(43) Pub. Date: Jun. 25, 2015

(54) APPARATUS AND METHOD FOR REACTING TO A CHANGE IN SUPPLY VOLTAGE

(71) Applicant: MARVELL ISRAEL (M.I.S.L) LTD., Yokneam (IL)

(72) Inventors: Ido BOURSTEIN, Pardes Hana (IL); Reuven ECKER, Haifa (IL)

(73) Assignee: MARVELL ISRAEL (M.I.S.L) LTD., Yokneam (IL)

(21) Appl. No.: 14/580,816

(22) Filed: Dec. 23, 2014

Related U.S. Application Data
(60) Provisional application No. 61/920,099, filed on Dec. 23, 2013.

(51) Int. Cl. H03L 7/00

(52) U.S. Cl. CPC H03L 7/00

(57) ABSTRACT

Aspects of the disclosure provide an integrated circuit (IC). The IC includes a clock generation and supply voltage monitoring circuit configured to monitor a supply voltage to the IC and selectively modify an operating frequency of the IC in response to a sensed change in the supply voltage. The IC further includes a frequency comparing and compensating circuit configured to output a control signal, based on the operating frequency, to a voltage supply to modify the supply voltage so as to compensate for changes in the operating frequency and return the operating frequency to a target operating frequency.

### INCORPORATION BY REFERENCE

This present disclosure claims the benefit of U.S. Provisional Application No. 61/920,099, “Adaptive Voltage Scaling and VDD Tracking” filed on Dec. 23, 2013, which is incorporated herein by reference in its entirety.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Various electronic systems provide a mechanism for ensuring long term stability of a voltage supply as a function of the performance of a circuit on a chip as measured on the chip itself. However, in the event of a sudden change in load, for example because of sudden change in activity of a CPU, a detrimental voltage drop or spike may occur even though the average supply voltage remains within an acceptable range of voltages.

For example, in an adaptive voltage scaling (AVS) system, which monitors performance of a chip as measured on the chip itself, a long-term steady state solution is provided. However, the AVS may react too slowly in the event of a sudden change in voltage.

For a discussion of such systems, please refer to U.S. Pat. No. 8,370,654, filed Mar. 24, 2010; U.S. Pat. No. 8,615,669, filed Sep. 13, 2012; application Ser. No. 14/134,807, filed Dec. 19, 2013; U.S. Pat. No. 8,046,601, filed Dec. 20, 2007; application Ser. No. 14/058,964, filed Oct. 21, 2013; and application Ser. No. 14/480,075, filed Sep. 8, 2014, all of which are incorporated herein by reference in their entireties.

### SUMMARY

Aspects of the disclosure provide an integrated circuit (IC). The IC includes a clock generation and supply voltage monitoring circuit configured to monitor a supply voltage to the IC and selectively modify an operating frequency of the IC in response to a sensed change in the supply voltage. The IC further includes a frequency comparing and compensating circuit configured to output a control signal, based on the operating frequency, to a voltage supply to modify the supply voltage so as to compensate for changes in the operating frequency and return the operating frequency to a target operating frequency.

In an embodiment, the clock generation and supply voltage monitoring circuit further comprises a voltage controlled oscillator configured to receive the supply voltage; and a control block configured to output a frequency control parameter to the voltage controlled oscillator.

In an example, the voltage controlled oscillator is configured to generate an output clock signal based upon the supply voltage and the frequency control parameter and to output the output clock signal to a circuit of the IC.

In an example, the output clock signal selectively reduces or increases the operating frequency of the IC in response to the sensed change in the supply voltage.

In an embodiment, the IC further includes a frequency monitoring circuit configured to monitor the operating frequency and to output a signal indicative of the operating frequency to the frequency comparing and compensating circuit.

In an example, the frequency comparing and compensating circuit further includes a frequency comparator configured to generate a correction signal based upon the signal indicative of the operating frequency; and a feedback generator configured to generate the control signal based upon the supply voltage and the correction signal and to output the control signal to a voltage supply providing the supply voltage.

In an example, the frequency comparing and compensating circuit is configured to generate the control signal as an analog signal and to provide the control signal to a voltage supply providing the supply voltage, the control signal configured to govern the supply voltage so as to return the operating frequency to the target operating frequency.

In an embodiment, the output clock signal is used for a system clock of the IC.

Aspects of the disclosure provide a method. The method includes monitoring a supply voltage to an integrated circuit (IC); selectively modifying an operating frequency of the IC in response to a sensed change in the supply voltage; and outputting a control signal, based on the operating frequency, to a voltage supply to modify the supply voltage so as to compensate for changes in the operating frequency and return the operating frequency to a target operating frequency.

Aspects of the disclosure provide a system. The system includes a voltage regulator configured to regulate a supply voltage based upon a control signal and an integrated circuit (IC). The IC includes a clock generation and supply voltage monitoring circuit configured to monitor a supply voltage to the IC and selectively modify an operating frequency of the IC in response to a sensed change in the supply voltage. The IC further includes a frequency comparing and compensating circuit configured to output a control signal, based on the operating frequency, to a voltage supply to modify the supply voltage so as to compensate for changes in the operating frequency and return the operating frequency to a target operating frequency.

### BRIEF DESCRIPTION OF THE DRAWINGS

Various embodiments of this disclosure that are proposed as examples will be described in detail with reference to the following figures, wherein like numerals reference like elements, and wherein:

FIG. 1 shows an electronics system according to an embodiment of the disclosure;

FIG. 2 shows a detailed view of the IC of FIG. 1 according to an embodiment of the disclosure;

FIG. 3 shows a detailed view of the clock generation and supply voltage monitoring circuit of FIG. 2 according to an embodiment of the disclosure;

FIG. 4 shows a detailed view of the frequency comparing and compensating circuit of FIG. 2 according to an embodiment of the disclosure;

FIG. 5 shows a relationship of IC activity, the supply voltage, and the operating frequency of the system clock of the CPU or other controller with respect to time according to an embodiment of the disclosure; and

FIG. 6 shows a simplified flowchart outlining a method according to an embodiment of the disclosure.

### DETAILED DESCRIPTION OF EMBODIMENTS

In an electronics system including an AVS system, performance of a chip is monitored as measured on the chip itself and a long-term steady state solution is provided. However, in the event that the AVS reacts too slowly to a sudden change in voltage, a fast acting solution is applied to the chip to prevent system failure. In an example, a fast acting clock generator and voltage monitor senses the sudden change of the voltage and quickly modifies the operating frequency of the chip in order to avoid system failure.

In an example, the quick modification in the operating frequency is monitored by a frequency monitor and an indication as to the modification of the operating frequency is forwarded to the AVS. In an example, the AVS receives the indication as to the modification of the operating frequency and governs a voltage supply to return the clock frequency to its target.

In an example, the operating frequency is a metric of chip performance. Performance of the chip is monitored and then feedback is provided to the voltage supply that governs the voltage to be supplied so the chip performance is kept within a prescribed performance range. In an example, when a supply voltage suddenly drops (or suddenly increases), which can be monitored quickly, the clock generator and voltage monitor provide quick compensation by quickly changing the clock frequency. However, this is not a desirable long term solution because it can adversely negatively impact system performance.

Long term performance stability is maintained by the AVS, which senses that chip performance has changed and provides a feedback signal to the voltage supply to compensate for the change in chip performance by increasing or reducing the voltage supplied to the chip until system performance is returned to its steady-state.

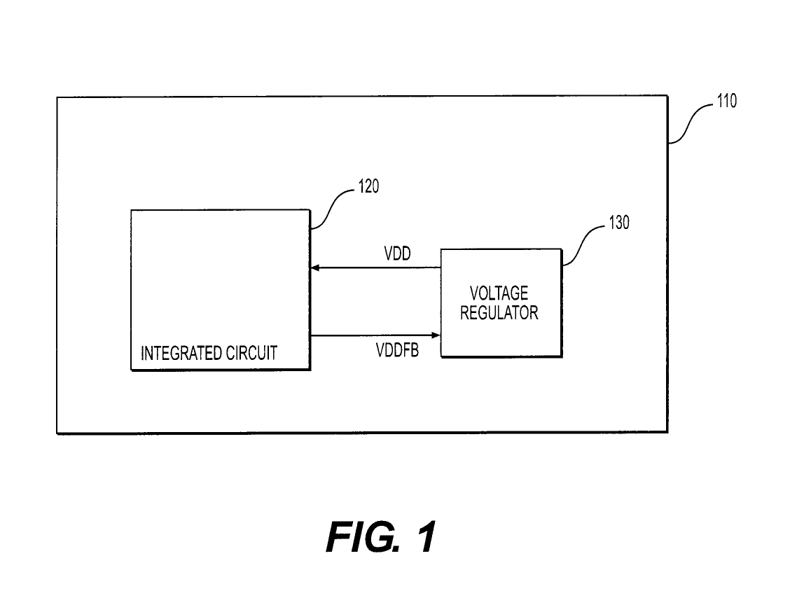

FIG. 1 shows a system 110 according to an embodiment of the disclosure. The system 110 includes an integrated circuit (IC) 120 and a voltage regulator 130. The voltage regulator 130 provides a supply voltage VDD to the IC 120. The IC 120 provides a control signal VDDFB to the voltage regulator 130, the control signal VDDFB being calculated on the IC 120 and indicative of its performance.

In an example, system 110 is an electronic system configured as an electronics device in which the IC 120 and the voltage regulator 130 are included on a circuit board. In an example, the IC 120 is a system-on-chip (SOC) that includes several integrated circuits, such as a central processing unit (CPU). In an example, the voltage regulator 130 regulates the supply voltage VDD to the IC 120 based upon the control signal VDDFB received from the IC 120. In an example, the voltage regulator 130 is a DC/DC converter that provides the supply voltage VDD to the IC 120. In example, voltage regulator 130 is any circuit suitable to provide the supply voltage VDD to the IC 120 based upon the control signal VDDFB. In an example, the voltage regulator 130 and the IC 120 form a feedback loop to generate and stabilize the supply voltage VDD. In an example, the voltage regulator 130 and the IC 120 are separate units both of which are disposed on a same circuit board. Alternatively, the voltage regulator 130 and the IC 120 are each disposed on separate circuit boards.

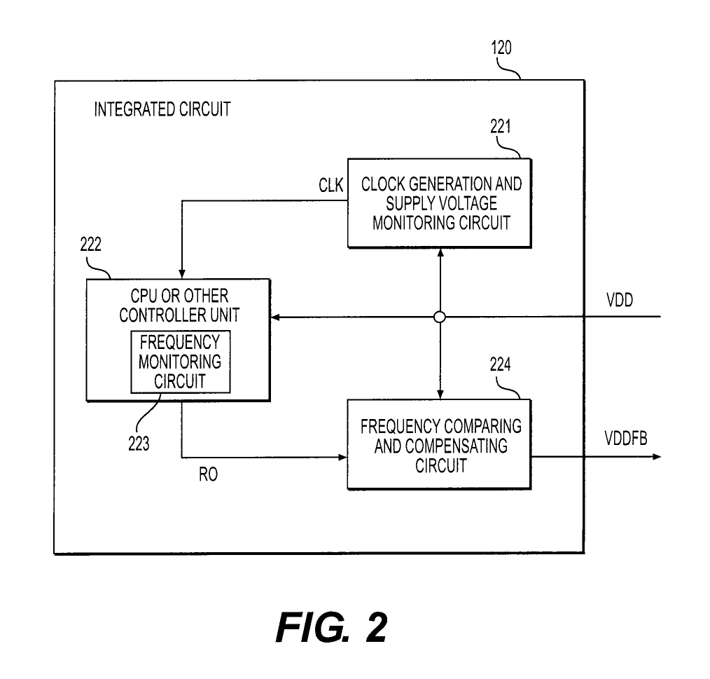

FIG. 2 shows a detailed view of the IC 120 according to an embodiment of the disclosure. In an example, the IC 120 includes a clock generation and supply voltage monitoring circuit 221, a CPU or other controller unit 222, a frequency monitoring circuit 223, and a frequency comparing and compensating circuit 224. In an example, each of the clock generation and supply voltage monitoring circuit 221, the CPU or other controller unit 222, and the frequency comparing and compensating circuit 224 receive the supply voltage VDD. In an example, the clock generation and supply voltage monitoring circuit generates and outputs a clock signal CLK to the CPU or other controller unit 222.

In an embodiment, the CPU or other controller unit 222 includes the frequency monitoring circuit 223. In an example, the frequency monitoring circuit 223 monitors an operating frequency of the CPU or other controller unit 222 and generates a signal indicative of the operating frequency of the CPU or other controller unit 222. In an example, the frequency monitoring circuit 223 counts a number of rising edges of a clock of the CPU or other controller unit 222 within a predetermined time. In an example, the frequency monitoring circuit 223 generates the signal indicative of the operating frequency of the clock of the CPU or other controller unit 222 based upon the number of rising edges within the predetermined time and outputs the signal indicative of the operating frequency as readout signal RO. In an example, the frequency monitoring circuit 223 is any circuit suitable to monitor the operating frequency of the CPU or other controller unit 222 and output the signal indicative of the operating frequency to the frequency comparing and compensating circuit 224. In an example, the readout signal RO is a digital signal. However, the readout signal RO is any suitable signal that is indicative of the operating frequency of the system clock and is output to the frequency comparing and compensating circuit 224. In an example, the CPU or other controller unit 222 is a main processor of the IC 120. In an example, the system clock of the CPU or other controller unit 222 is a fundamental clock of the main processor of the IC 120. In an example, the CPU or other controller unit 222 uses the clock signal CLK output from the clock generation and supply voltage monitoring circuit 221 as its system or fundamental clock. In an example, the frequency monitoring circuit 223 monitors the operating frequency of the system or fundamental clock of the CPU or other controller unit 222 and outputs the readout signal RO indicative of the operating frequency of the system or fundamental clock of the CPU or other controller unit 222 to the frequency comparing and compensating circuit 224.

In an example, the frequency monitoring circuit 223 is a counter of a Digital Ring Oscillator (not shown) disposed on the CPU or other controller unit 222. In an example, one of the clock of the CPU or other controller unit 222 and an output of the DRO are selected and counted by the counter of the DRO. In an example, the counter of the DRO outputs the readout signal RO to the frequency comparing and compensating circuit 224. In an example, the frequency monitoring circuit 223 is not disposed within the CPU or other controller unit 222.

In an embodiment, the frequency comparing and compensating circuit 224 receives the readout signal RO and generates the control signal VDDFB based upon the readout signal RO. In an example, the frequency comparing and compensating circuit 224 outputs the control signal VDDFB as an analog signal indicative of IC performance to the voltage regulator 130. Essential functionality of an example embodiment for generation of the control signal VDDFB, based on system performance, can be found in detail within U.S. Pat. No. 8,370,654, filed Mar. 24, 2010; U.S. Pat. No. 8,615,669, filed Sep. 13, 2012; application Ser. No. 14/134,807, filed Dec. 19, 2013; U.S. Pat. No. 8,046,601, filed Dec. 20, 2007; application Ser. No. 14/058,964, filed Oct. 21, 2013; and application Ser. No. 14/480,075, filed Sep. 8, 2014, for example.

In an embodiment, the clock generation and supply voltage monitoring circuit 221, the frequency monitoring circuit 223, and the frequency comparing and compensating circuit 224, in combination with the voltage regulator 130, are used as a replacement for a frequency locked loop (FLL) or a phase locked loop (PLL) used to provide the fundamental clock to the CPU or other controller unit 222. In an example, the clock generation and supply voltage monitoring circuit 221, the frequency monitoring circuit 223, and the frequency comparing and compensating circuit 224, in combination with the voltage regulator 130, are used in parallel with a FLL or PLL (not shown). In an example, one of the clock signal CLK and an output from the PLL is selected as the fundamental clock to the CPU or other controller 222.

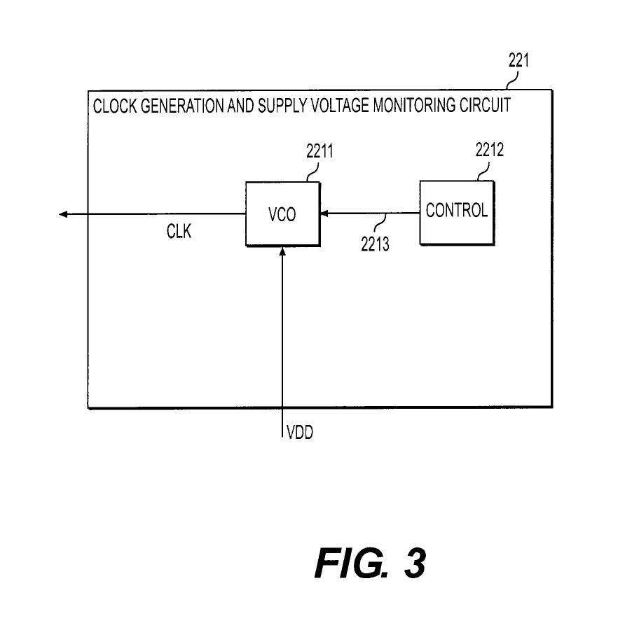

FIG. 3 shows a detailed view of the clock generation and supply voltage monitoring circuit 221 according to an embodiment of the disclosure. In an embodiment, the clock generation and supply voltage monitoring circuit 221 includes a voltage controlled oscillator 2211 and a control block 2212. In an example, the voltage controlled oscillator 2211 receives the supply voltage VDD and outputs the clock signal CLK. In an example, the voltage controlled oscillator 2211 outputs the clock signal CLK to the CPU or other controller unit 222. In an example, the control block 2212 outputs one or more control parameters 2213 to the voltage controlled oscillator 2211. The voltage controller oscillator 2211 generates the clock signal CLK having a frequency determined based upon the supply voltage VDD and the one or more control parameters 2213.

In an embodiment, the one or more control parameters 2213 include K1, K2, and S (not shown). In an example, K1 is a gross range frequency control parameter, K2 is a fine tune frequency control parameter, and S is a slope control defining a relationship between the supply voltage VDD and the frequency of the clock signal CLK. In an example, the relationship between the supply voltage VDD and the frequency of the clock signal CLK is linear.

In an embodiment, the one or more control parameters 2213 are pre-programmed in the control block 2212. In an example, the one or more control parameters 2213 are provided to the control block 2212 based upon frequency-voltage characteristics of the IC 120, which will be described later.

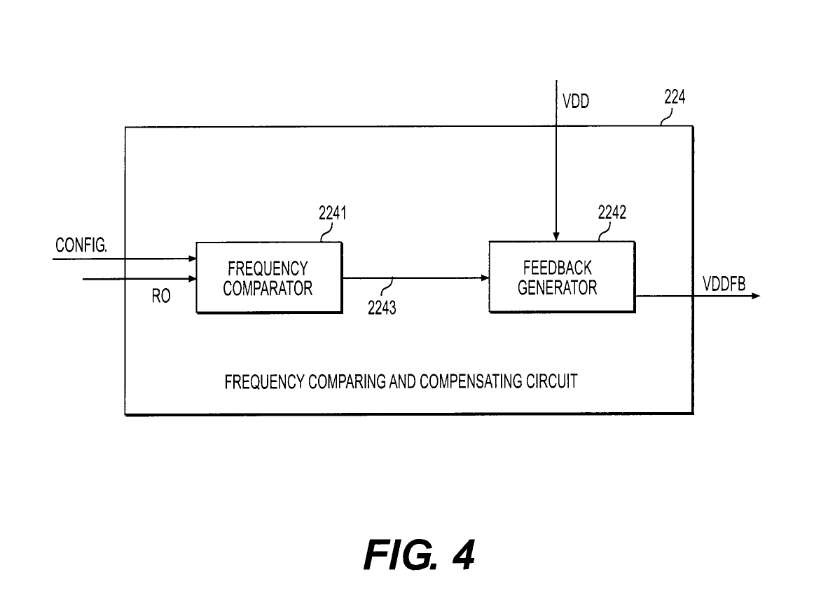

FIG. 4 shows a detailed view of the frequency comparing and compensating circuit 224 according to an embodiment of the disclosure. In an embodiment, the frequency comparing and compensating circuit 224 includes a frequency comparator 2241 and a feedback generator 2242. In an example, the frequency comparator 2241 receives the readout signal RO. The frequency comparator 2241 generates a correction signal 2243 based upon the readout signal RO. In an example, the feedback generator 2242 receives the supply voltage VDD and the correction signal 2243. The feedback generator 2242 generates the control signal VDDFB based upon the voltage VDD and the correction signal 2243. In an example, the feedback generator 2242 outputs the control signal VDDFB to the voltage regulator 130.

In an embodiment, the frequency comparator 2241 includes any suitable logic circuit, such as analog logic circuit, digital logic circuit, and the like. In an embodiment, the logic circuit generates the correction signal 2243 based on the readout signal RO as well as a predetermined target value. In an example, the predetermined target value is a target operating frequency of the IC 120. In an example, the target operating frequency of the IC is a target operating frequency of the CPU or other controller unit 222. In an example, the target operating frequency of the CPU or other controller unit 222 is a target operating frequency of the system or fundamental clock of the CPU or other controller unit 222. The correction signal 2243 generated by the frequency comparator 2241 is a signal suitable for subsequently generating the control signal VDDFB to control the voltage regulator 130. In an example, the correction signal 2243 is generated as an analog signal that is indicative of a need to increase or to reduce the voltage supply VDD so as to meet the predetermined target value.

In an embodiment, the readout signal RO is a digital signal, and the frequency comparator 2241 includes a digital logic circuit to generate the correction signal 2243 as a digital signal based on the readout signal RO. In an example, the readout signal RO includes any suitable signal, and the frequency comparator 2241 includes any suitable logic circuit to generate the correction signal 2243 based on the readout signal RO and the predetermined target value. In an embodiment, the correction signal 2243 includes an offset value indicative of a difference between the operating frequency of the CPU or other controller unit 222 and the predetermined target value. In an embodiment, the correction signal 2243 includes an offset voltage value.

In an embodiment, the frequency comparator 2241 stores the predetermined target value. In an example, the frequency comparator 2241 receives configuration and control data CONFIG that includes the predetermined target value. In an example, the frequency comparator 2241 receives the configuration and control data from the CPU or other controller unit 222.

In an embodiment, the frequency comparator 2241 compares a value indicative of the operating frequency of the CPU or other controller unit 222 received from the received readout signal RO with the predetermined target value to generate a difference value. In an example, the difference value is indicative of a difference between the actual operating frequency of the CPU or other controller unit 222 and a target operating frequency. In an example, the difference value is indicative of a difference between the actual operating frequency of the system or fundamental clock of the CPU or other controller unit 222 and the target operating frequency of the system or fundamental clock of the CPU or other controller unit 222. In an example, the frequency comparator 2241 determines the correction signal 2243 based on the generated difference value, which is indicative of a supply voltage (or an offset to the existing supply voltage VDD) that is needed in order to meet the target operating frequency.

In an embodiment, the correction signal 2243 is determined based upon a predetermined step size. In an example, the predetermined step size is a maximum value that may be output by frequency comparator 2241 as the correction signal 2243.

In an embodiment, the frequency comparator 2241 determines the correction signal 2243 based upon a predetermined maximum value of the supply voltage VDD and a predetermined minimum value of the supply voltage VDD. In an example, the predetermined maximum value and the predetermined minimum value define operational limits of the frequency comparing and compensating circuit 224. In an example, the frequency comparator 2241 stores the predetermined maximum value and the predetermined minimum value. In an example, the frequency comparator 2241 receives the predetermined maximum value and the predetermined minimum value within the configuration and control data received from the CPU or other controller unit 222. In an example, the predetermined maximum value and the predetermined minimum value are set based upon the frequency-voltage characteristics of the IC 120, which will be described later.

In an embodiment, feedback generator 2242 includes any suitable circuit that generates the control signal VDDFB based upon the correction signal 2243 and the supply voltage VDD. In an example, the feedback generator 2242 generates the control signal VDDFB as combinational result of the supply voltage VDD in combination with the correction signal 2243 providing a voltage offset that is indicative of the operating frequency of the CPU or other controller unit 222 relative to the target operating frequency of the CPU or other controller unit 222. In an example, the feedback generator 2242 is a combiner circuit (not shown) that combines the correction signal 2243 (as a voltage) with the supply voltage VDD.

In an embodiment, feedback generator 2242 is a summing circuit (not shown) that combines the supply voltage VDD with the correction signal 2243 (as a voltage) to generate the control signal VDDFB. In an example, the correction signal 2243 is generated as a digital signal, and the feedback generator 2242 includes a digital logic circuit to generate the control signal VDDFB as a digital signal based upon the correction signal 2243. In an example, the correction signal 2243 is generated as an analog signal, and the feedback generator 2242 includes an analog logic circuit to generate the control signal VDDFB as an analog signal based upon the correction signal 2243. In an example, the voltage regulator 130 will either increase the supply voltage VDD, decrease the supply voltage VDD, or allow the supply voltage VDD to remain the same, based on a magnitude of the control signal VDDFB. In an example, the voltage regulator 130 will either increase the supply voltage VDD, decrease the supply voltage VDD, or allow the supply voltage VDD to remain the same, based on a digital value of the control signal VDDFB.

Functionality as to controlling the voltage regulator 130 with control signal VDDFB can be found within U.S. Pat. No. 8,370,654, filed Mar. 24, 2010; U.S. Pat. No. 8,615,669, filed Sep. 13, 2012; application Ser. No. 14/134,807, filed Dec. 19, 2013; U.S. Pat. No. 8,046,601, filed Dec. 20, 2007; application Ser. No. 14/058,964, filed Oct. 21, 2013; and application Ser. No. 14/480,075, filed Sep. 8, 2014, for example.

The setting of the one or more control parameters 2213 of the control block 2212 and the predetermined maximum value and the predetermined minimum value of the frequency comparator 2241 based upon the frequency-voltage characteristics of the IC 120 will be briefly discussed (not shown). In an embodiment, the setting of the one or more control parameters 2213 and the predetermined maximum value and the predetermined minimum value is performed for every IC 120 that is manufactured. In an example, the setting of the one or more control parameters 2213 and the predetermined maximum value and the predetermined minimum value is performed for a representative number of IC 120.

In an example, the frequency comparator 2241 is set to an open loop mode. In an example, in the open loop mode, the predetermined maximum value of the supply voltage VDD and the predetermined minimum value of the supply voltage VDD are set to the same value. In an example, this same value is a representative supply voltage VDD. In an example, for this representative supply voltage VDD, the control parameters K1, K2, and S are changed from their lower limits to their upper limits and frequency-voltage characteristics of the clock generation and supply voltage measuring circuit 221 are measured at each value of the control parameters K1, K2, and S from their lower limits to their upper limits. In an example, the process is repeated for every value of the representative supply voltage from its lower limit to its upper limit.

In an example, the measured frequency-voltage characteristics of the clock generation and supply voltage measuring circuit 221 are compared to the frequency-voltage characteristics of the system 120. In an example, a frequency-voltage curve, of several frequency-voltage curves representing the frequency-voltage characteristics of the clock generation and supply voltage measuring circuit 221, is selected. In an example, the selected frequency-voltage curve is one that is below a frequency-voltage curve representing the frequency-voltage characteristics of the system 120.

In an embodiment, the predetermined maximum value and the predetermined minimum value are set based upon a plurality of frequency-voltage curves representing the frequency-voltage characteristics of the clock generation and supply voltage measuring circuit 221 that are below the frequency-voltage curve representing the frequency-voltage characteristics of the system 120.

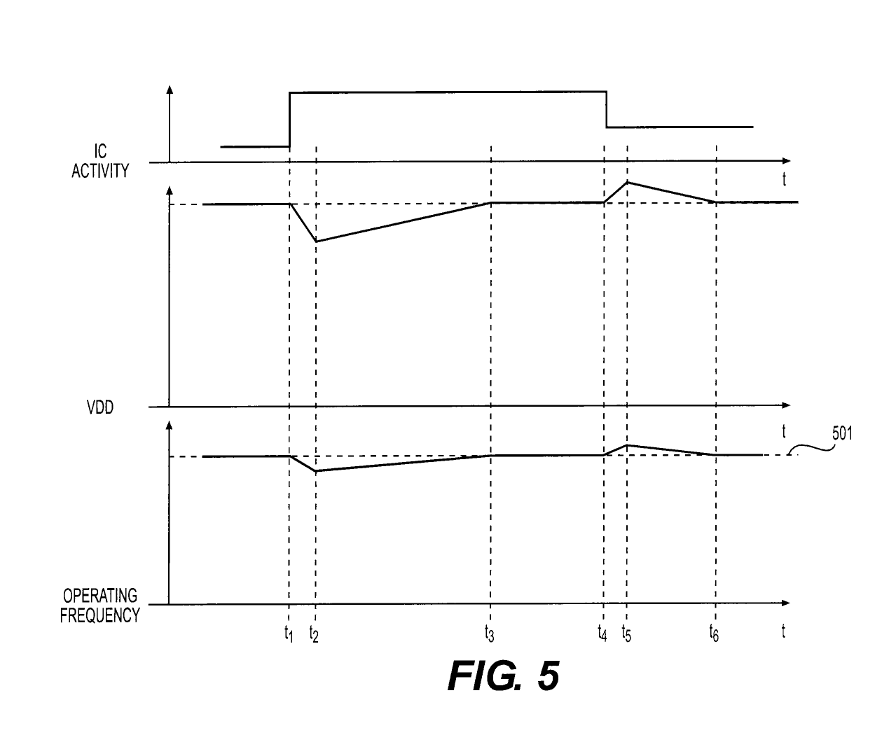

FIG. 5 shows a relationship of IC 120 activity, the supply voltage VDD, and the operating frequency of the CPU or other controller 222 with respect to time according to an embodiment of the disclosure.

In an embodiment, at time t1, activity of the IC 120 rapidly increases. In an example, this rapid increase in activity corresponds to a rapid increase in processing operations performed by the CPU or other controller unit 222. In an example, the rapid increase in processing operations performed by the CPU or other controller unit 222 corresponds to initiation of video processing and/or gaming processing on the CPU or other controller unit 222. In an example, the rapid increase in processing operations performed by the CPU or other controller unit 222 corresponds to initiation of encryption processing and/or decryption processing by the CPU or other controller unit 222.

In embodiment, due to this sudden increase in activity of the IC 120, the supply voltage VDD also rapidly drops. In an example, in response to the rapid drop in the supply voltage VDD, the clock generation and supply voltage monitoring circuit 221 rapidly outputs the clock signal CLK with a corresponding reduced frequency to avoid a fatal system imbalance resulting from the sudden drop in the supply voltage VDD. In an example, the clock signal CLK with the reduced frequency is received by the CPU or other controller unit 222. In an example, the CPU or other controller unit 222 uses the clock signal CLK with the reduced frequency as its system or fundamental clock. In an example, the frequency of the system or fundamental clock of the CPU or other controller unit 222 is thus reduced. In an example, the reduction in the frequency of the system or fundamental clock results in a temporary reduction in system performance of the IC 120, which is sensed by the frequency monitoring circuitry 223.

In an embodiment, the voltage controller oscillator 2211 generates the clock signal CLK with the reduced frequency based upon the dropped supply voltage VDD and the one or more control parameters 2213.

In an embodiment, by time t2, the frequency comparing and compensating circuit 224 senses the drop in performance resulting from the reduced frequency and outputs the control signal VDDFB to the voltage regulator 130. Inasmuch as reduced system performance is sensed, as seen in the embodiment depicted in FIG. 5, the control signal VDDFB is configured to cause an increase in the supply voltage VDD. As a result, the frequency of the clock signal CLK gradually increases to return the system to a steady state in which both system performance, as measured for example as the operating frequency of the CPU or other controller 222, and supply voltage VDD meet target parameters. In an example, the frequency monitoring circuit 223 outputs the signal indicative of the operating frequency of the CPU or other controller unit 222 as readout signal RO. In an example, the frequency comparing and compensating circuit 224 receives the readout signal RO from the frequency monitoring circuit 223. In an example, the frequency comparing and compensating circuit 224 generates the control signal VDDFB based upon the readout signal RO and the supply voltage VDD.

In an embodiment, the frequency comparator 2241 receives the readout signal RO. In an example, the frequency comparator 2241 compares the value indicative of the operating frequency of the CPU or other controller unit 222 sent as readout signal RO with the target operating frequency. In an example, the frequency comparator 2241 generates a voltage offset as the correction signal 2243 corresponding to a difference between the value indicative of the operating frequency of the CPU or other controller unit 222 and the target operating frequency.

In an embodiment, the frequency comparator 2241 outputs the correction signal 2243 to the feedback generator 2242. In an example, feedback generator 2242 adds the correction signal 2243 to the supply voltage VDD to generate the control signal VDDFB. In an example, the feedback generator 2242 outputs the control signal VDDFB to the voltage regulator 130. In an example, the voltage regulator 130 modifies the supply voltage VDD responsively to the control signal VDDFB. In an example, as seen from t2 to t3 in FIG. 5, the supply voltage VDD is increased until the operating frequency of the CPU or other controller unit 222 meets the target operating frequency 501.

In an embodiment, as the supply voltage VDD is increased, the clock generation and voltage supply monitoring unit 221 increases the frequency of the clock signal CLK. In an example, the clock signal CLK with the increased frequency is output to the CPU or other controller unit 222 and is used as the operating frequency of the system or fundamental clock of the CPU or other controller unit 222. In an example, the frequency monitoring circuit 223 outputs readout signal RO indicative of the increase in operating frequency of the CPU or other controller unit 222 to the frequency comparing and compensating circuit 224.

In an embodiment, the above process continues and repeats, as necessary, until the operating frequency of the system clock of the CPU or other controller unit 222 reaches the target operating frequency 501, as seen between times t2 and t3 of FIG. 5. In an embodiment, the frequency monitoring circuit 223 and the frequency comparing and compensating circuit 224 continuously operate to monitor the operating frequency of the CPU or other controller 222 and control the voltage regulator 130 with the control signal VDDFB. In an embodiment, the clock generation and supply voltage monitoring circuit 221 operates to provide the clock signal CLK to the CPU or other controller unit 222. In example, the clock generation and supply voltage monitoring unit 221 quickly reduces the operating frequency of the CPU or other controller 222 with clock signal CLK when sensing the sudden drop in supply voltage VDD.

In an embodiment, at time t4, the activity of the IC is suddenly reduced. In an example, this reduction in activity corresponds to a sudden decrease in processing operations performed by the CPU or other controller 222. In an example, the sudden decrease in processing operations performed by the CPU or other controller unit 222 corresponds to cessation of the video processing and/or the gaming processing on the CPU or other controller unit 222. In an example, the sudden decrease in processing operations performed by the CPU or other controller unit 222 corresponds to cessation of the encryption processing and/or the decryption processing by the CPU or other controller unit 222.

In an embodiment, due to this decrease in activity of the IC, the supply voltage VDD rapidly increases. In an example, in response to the rapid increase in the supply voltage VDD, the clock generation and supply voltage monitoring circuit 221 outputs the clock signal CLK with a corresponding increase in frequency to accommodate the increased supply voltage VDD and prevent the system from crashing.

In an embodiment, the voltage controller oscillator 2211 generates the clock signal CLK with the increased frequency based upon the increased supply voltage VDD and the one or more control parameters 2213.

In an embodiment, by time t5, the frequency comparing and compensating circuit 224 has determined that the operating frequency is above the target frequency 501 and based on the increased operating frequency outputs the control signal VDDFB to the voltage regulator 130 to cause a gradual decrease in the supply voltage VDD and thereby causes a gradual decrease in the frequency of the clock signal CLK until the operating frequency returns to the target frequency 501. In an example, the frequency monitoring circuit 223 outputs the signal indicative of the operating frequency of the CPU or other controller unit 222 as readout signal RO. In an example, the frequency comparing and compensating circuit 224 receives the readout signal RO from the frequency monitoring circuit 223. In an example, the frequency comparing and compensating circuit 224 generates the control signal VDDFB based upon the readout signal RO.

In an embodiment, the frequency comparator 2241 receives the readout signal RO. In an example, the frequency comparator 2241 compares the value indicative of the operating frequency of the CPU or other controller unit 222 sent as readout signal RO with the target operating frequency. In an example, the frequency comparator 2241 generates a voltage offset as the correction signal 2243 corresponding to a difference between the value indicative of the operating frequency of the CPU or other controller unit 222 and the target operating frequency.

In an embodiment, the frequency comparator 2241 outputs the correction signal 2243 to the feedback generator 2242. In an example, feedback generator 2242 adds the correction signal 2243 to the supply voltage VDD to generate the control signal VDDFB. In an example, the feedback generator 2242 outputs the control signal VDDFB to the voltage regulator 130. In an example, the voltage regulator 130 decreases the supply voltage VDD in accordance with the control signal VDDFB. In an example, as seen from t5 to t6 in FIG. 5, the supply voltage VDD is decreased until the operating frequency of the CPU or other controller unit 222 meets the target operating frequency 501.

In an embodiment, as the supply voltage VDD is decreased, the clock generation and voltage supply monitoring unit 221 decreases the frequency of the clock signal CLK. In an example, the voltage controller oscillator 2211 outputs the clock signal CLK having the decreased frequency based upon the decreased supply voltage VDD. In an embodiment, the clock signal CLK having the decreased frequency is output to the CPU or other controller unit 222 and is used as the operating frequency of the system or fundamental clock of the CPU or other controller unit 222. In an example, the clock signal CLK is the system or fundamental clock of the CPU or other controller 222. In an example, the frequency monitoring circuit 223 outputs readout signal RO indicative of the decrease in operating frequency of the CPU or other controller unit 222 to the frequency comparing and compensating circuit 224.

In an embodiment, the above process continues and repeats, as necessary, until the operating frequency of the system clock of the CPU or other controller unit 222 reaches the target operating frequency 501, as seen between times t5 and t6 of FIG. 5. In an embodiment, the frequency monitoring circuit 223 and the frequency comparing and compensating circuit 224 continuously operate to monitor the operating frequency of the CPU or other controller 222 and control the voltage regulator 130 with the control signal VDDFB. In an embodiment, the clock generation and supply voltage monitoring circuit 221 operates to provide the clock signal CLK to the CPU or other controller unit 222. In example, the clock generation and supply voltage monitoring unit 221 increases the operating frequency of the CPU or other controller 222 with clock signal CLK when sensing the sudden increase in supply voltage VDD.

In an embodiment, the clock generation and voltage supply monitoring circuit 221 and the frequency comparing and compensating circuit 224, along with the voltage regulator 130, form a frequency feedback loop that responds quickly to a rapid drop or increase in supply voltage VDD by correspondingly quickly modifying the operating frequency of the CPU or other controller unit 222 and then bringing the operating frequency of the CPU or other controller unit 222 back to the target operating frequency after the rapid drop or increase in supply voltage VDD. In an example, the frequency monitoring circuit 223 also forms the frequency feedback loop or FLL.

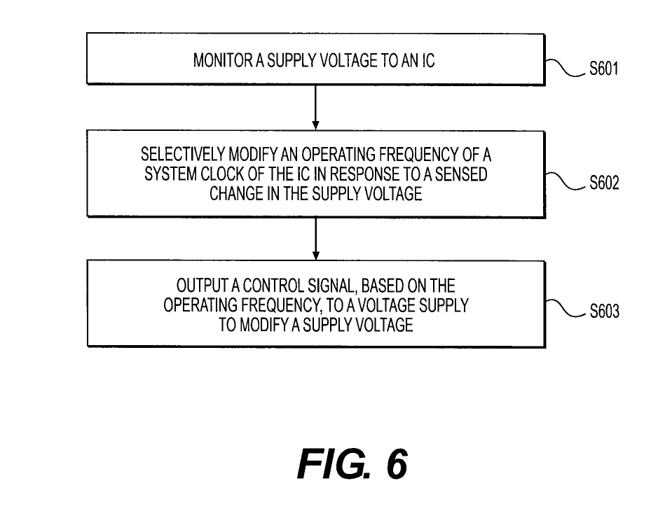

FIG. 6 shows a simplified flowchart outlining a method according to an embodiment of the disclosure.

At S601, the clock generation and supply voltage monitoring circuit 221 monitors the supply voltage VDD supplied to the IC 120, and the method continues to S602.

At S602, the clock generation and supply voltage monitoring circuit 221 selectively modifies the operating frequency of the IC 120 in response to a sensed change in the supply voltage VDD, and the method continues to S603. In an embodiment, this change is a short term change.

At S603, the frequency comparing and compensating circuit 224 outputs the control signal VDDFB, based upon a performance characteristic, for example, the operating frequency of the IC 120, to the voltage regulator 130 to modify the supply voltage VDD so as to compensate for changes in the performance characteristic of the IC 120 and to return performance of the IC 120 to a target performance.

In an embodiment, any or all of S601 through S603 may be repeated as necessary to return the operating frequency of the IC 120 to the target operating frequency. In an embodiment, S603 is performed continuously to control the voltage regulator 130 with the control signal VDDFB. In an embodiment, S602 is performed when a sudden change in the voltage supply VDD is sensed.

In an embodiment, at S602, the clock generation and supply voltage monitoring circuit 221 generates the clock signal CLK based upon the supply voltage VDD and the one or more frequency parameters 2213 and outputs the clock signal CLK to a circuit of the IC 120.

In an embodiment, at S602, the clock generation and supply voltage monitoring circuit 221 selectively reduces or increases the operating frequency of the IC 120 based upon the clock signal CLK in response to a sensed change in the supply voltage VDD.

In an embodiment, at S603, the frequency monitoring circuit 223 monitors the operating frequency of the IC 120 and outputs the readout signal RO indicative of the operating frequency the IC 120.

In an embodiment, at S603, the frequency comparator 2241 generates the correction signal 2243 based upon the readout signal RO, and the feedback generator 2242 generates the control signal VDDFB based upon the supply voltage VDD and the correction signal 2243 and outputs the control signal VDDFB to the voltage regulator 130.

In an example, at S603, the frequency comparing and compensating circuit 224 generates the control signal VDDFB as an analog signal so as to return the operating frequency of the system clock of the IC 120 the target operating frequency. Alternatively, the control signal VDDFB includes a digital value.

According to the embodiments, a drop in the supply voltage VDD is sensed and the operating frequency of the system clock of the CPU or other controller unit 222 is correspondingly reduced. According to the embodiments, an increase in the supply voltage VDD is sensed and the operating frequency of the system clock of the CPU or other controller unit 222 is correspondingly increased. According to the examples, the operating frequency of the system clock of the CPU or other controller unit 222 is brought back to the target operating frequency by virtue of the feedback loop formed by the clock generation and supply voltage monitoring unit 221 and the frequency comparing and compensating circuit 224. According to the examples, failure of the CPU or other controller unit 222 when the supply voltage VDD suddenly drops or suddenly increases is prevented.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. An integrated circuit (IC), comprising:
a clock generation and supply voltage monitoring circuit configured to monitor a supply voltage to the IC and selectively modify an operating frequency of the IC in response to a sensed change in the supply voltage; and
a frequency comparing and compensating circuit configured to output a control signal, based on the operating frequency, to a voltage supply to modify the supply voltage so as to compensate for changes in the operating frequency and return the operating frequency to a target operating frequency.

2. The IC of claim 1, wherein the clock generation and supply voltage monitoring circuit further comprises:
a voltage controlled oscillator configured to receive the supply voltage; and
a control block configured to output a frequency control parameter to the voltage controlled oscillator,
wherein the voltage controlled oscillator is configured to generate an output clock signal based upon the supply voltage and the frequency control parameter and to output the output clock signal to a circuit of the IC.

3. The IC of claim 2, wherein the output clock signal selectively reduces or increases the operating frequency of the IC in response to the sensed change in the supply voltage.

4. The IC of claim 1, further comprising:
a frequency monitoring circuit configured to monitor the operating frequency and to output a signal indicative of the operating frequency to the frequency comparing and compensating circuit.

5. The IC of claim 4, wherein the frequency comparing and compensating circuit further comprises:
a frequency comparator configured to generate a correction signal based upon the signal indicative of the operating frequency; and
a feedback generator configured to generate the control signal based upon the supply voltage and the correction signal and to output the control signal to a voltage supply providing the supply voltage.

6. The IC of claim 1, wherein the frequency comparing and compensating circuit is configured to generate the control signal as an analog signal and to provide the control signal to a voltage supply providing the supply voltage, the control signal configured to govern the supply voltage so as to return the operating frequency to the target operating frequency.

7. The IC of claim 2, wherein the output clock signal is used for a system clock of the IC.

8. A method, comprising:
monitoring a supply voltage to an integrated circuit (IC);
selectively modifying an operating frequency of the IC in response to a sensed change in the supply voltage; and
outputting a control signal, based on the operating frequency, to a voltage supply to modify the supply voltage so as to compensate for changes in the operating frequency and return the operating frequency to a target operating frequency.

9. The method of claim 8, further comprising:
generating an output clock signal based upon the supply voltage and a frequency control parameter; and
outputting the output clock signal to a circuit of the IC.

10. The method of claim 9, wherein selectively modifying the operating frequency of the IC includes selectively reducing or increasing the operating frequency of the IC based upon the output clock signal in response to the sensed change in the supply voltage.

11. The method of claim 8, further comprising:
monitoring the operating frequency; and
outputting a signal indicative of the operating frequency.

12. The method of claim 11, further comprising:
generating a correction signal based upon the signal indicative of the operating frequency;
generating the control signal based upon the supply voltage and the correction signal; and
outputting the control signal to a voltage supply providing the supply voltage.

13. The method of claim 9, wherein generating the control signal includes:
generating the control signal as an analog signal; and
providing the control signal to a voltage supply providing the supply voltage, the control signal configured to govern the supply voltage so as to return the operating frequency to the target operating frequency.

14. A system, comprising:
a voltage regulator configured to regulate a supply voltage based upon a control signal; and
an integrated circuit (IC) that comprises:
a clock generation and supply voltage monitoring circuit configured to monitor the supply voltage and selectively modify an operating frequency of the IC in response to a sensed change in the supply voltage, and
a frequency comparing and compensating circuit configured to output the control signal, based on the operating frequency, to the voltage regulator to modify the supply voltage so as to compensate for changes in the operating frequency and return the operating frequency to a target operating frequency.

15. The system of claim 14, wherein the clock generation and supply voltage monitoring circuit further comprises:
a voltage controlled oscillator configured to receive the supply voltage; and
a control block configured to output a frequency control parameter to the voltage controlled oscillator,
wherein the voltage controlled oscillator is configured to generate an output clock signal based upon the supply voltage and the frequency control parameter and to output the output clock signal to a circuit of the IC.

16. The system of claim 15, wherein the output clock signal selectively reduces or increases the operating frequency of the IC in response to the sensed change in the supply voltage.

17. The system of claim 14, further comprising:
a frequency monitoring circuit configured to monitor the operating frequency and to output a signal indicative of the operating frequency to the frequency comparing and compensating circuit.

18. The system of claim 17, wherein the frequency comparing and compensating circuit further comprises:
a frequency comparator configured to generate a correction signal based upon and the signal indicative of the operating frequency; and
feedback generator configured to generate the control signal based upon the supply voltage and the correction signal and to output the control signal to the voltage regulator.

19. The system of claim 14, wherein the frequency comparing and compensating circuit is configured to generate the control signal as an analog signal and to provide the control signal to the voltage regulator, the control signal configured to govern the supply voltage so as to return the operating frequency to the target operating frequency.

20. The system of claim 15, wherein the output clock signal is used for a system clock of the IC.
